(19) United States
(12) Patent Application Publication
(10) Pub. No.: US 2025/0370039 A1
(43) Pub. Date: Dec. 4, 2025

(54) AI EMBEDDING VECTOR DATA BASE CALIBRATION ARCHITECTURE

(71) Applicant: Tektronix, Inc., Beaverton, OR (US)

(72) Inventors: John J. Pickerd, Hillsboro, OR (US); Kan Tan, Portland, OR (US); Hannah Lee, Acworth, GA (US)

(21) Appl. No.: 19/192,166

(22) Filed: Apr. 28, 2025

Related U.S. Application Data
(60) Provisional application No. 63/642,629, filed on May 3, 2024.
(60) Provisional application No. 63/717,842, filed on Nov. 7, 2024.

(51) Int. Cl. G01R 31/317; G01R 31/3183; G01R 31/319; G06F 16/22

(52) U.S. Cl. CPC G01R 31/3172; G01R 31/318371; G01R 31/31905; G06F 16/2237

(57) ABSTRACT

A test and measurement system has a test and measurement instrument that includes a connection to a device under test (DUT); one or more analog-to-digital converters (ADCs) to receive and convert a signal from the DUT to one or more digital waveforms; and one or more processors to: receive the one or more digital waveforms corresponding to one set of tuning parameters applied to the DUT; build one or more image tensors of the one or more digital waveforms; use an artificial intelligence embedding model that generates one or more text strings from metadata and embeds the metadata and the one or more image tensors into a vector; access a vector database; receive a set of indexes having a number of indexes corresponding to a number of matches; use the set of indexes to find one or more sets of optimal tuning parameters; and validate operation of the DUT.

### CROSS-REFERENCE TO RELATED APPLICATIONS

This disclosure is a non-provisional of and claims benefit from U.S. Provisional Application No. 63/642,629, titled “AI EMBEDDING VECTOR DATA BASE CALIBRATION ARCHITECTURE,” filed on May 3, 2024, and U.S. Provisional Application No. 63/717,842, titled “AI EMBEDDING VECTOR DATA BASE ARCHITECTURE FOR CALIBRATION OF A DEVICE UNDER TEST IN MANUFACTURING,” filed on Nov. 7, 2024, the disclosures of both of which are incorporated herein by reference in their entirety.

### TECHNICAL FIELD

This disclosure relates to test and measurement systems and methods, and more particularly to applying machine learning to measurements of a signal from a device under test (DUT).

### BACKGROUND

U.S. Pat. No. 11,923,896, issued Mar. 5, 2024, titled “OPTICAL TRANSMITTER TUNING USING MACHINE LEARNING,” hereinafter “the '896 patent,” the contents of which are hereby incorporated by reference into this disclosure, and U.S. Pat. No. 11,923,895, issued Mar. 5, 2024, titled “OPTICAL TRANSMITTER TUNING USING MACHINE LEARNING AND REFERENCE PARAMETERS,” hereinafter “the '895 patent,” the contents of which are hereby incorporated by reference into this disclosure, both describe systems and methods for applying a trained machine learning system to make a prediction of optimal tuning parameters for an optical transceiver DUT. Embodiments of these systems may also be generally referred to in this disclosure as OptaML and/or OptaML Pro.

Other Tektronix patents and patent applications describe other ways to improve the resolution of key features, extend the record length of segments placed in the image, and more efficiently use the image space for even more extracted feature sets. For example, U.S. patent application Ser. No. 17/747,954, filed May 18, 2022, titled “SHORT PATTERN WAVEFORM DATABASE BASED MACHINE LEARNING FOR MEASUREMENT,” hereinafter “the '954 application,” the contents of which are hereby incorporated by reference into this application, describes systems and methods for applying a trained machine learning system to make predictions of measurements for signals received from a device under test (DUT). One example signal measurement is Transmitter and Dispersion Eye Closure Quaternary (TDECQ) when the DUT is, for example, an optical transceiver. Input to the machine learning systems described in the '954 application, both for training and runtime, is in the form of tensor images that are built using graphical representations of particular short pattern segments within long waveforms acquired from DUTs.

As another example, U.S. patent application Ser. No. 18/199,846, filed May 19, 2023, titled “AUTOMATED CAVITY FILTER TUNING USING MACHINE LEARNING,” hereinafter “the '846 application,” the contents of which are hereby incorporated by reference into this application, describes systems and methods for applying a trained machine learning system for making predictions of optimal positions of tuning elements in a tunable device under test, such as a cavity filter. Input to the machine learning systems described in the '846 application, both for training and runtime, is in the form of tensor images that are built using graphical representations of scattering parameters (S-parameters) or other parameters that characterize DUTs.

As another example, U.S. patent application Ser. No. 18/665,258, filed Nov. 28, 2024, “USER INTERFACE FOR A TENSOR BUILDER TO CONSTRUCT IMAGES FOR INPUT TO MACHINE LEARNING,” hereinafter “the '258 application,” the contents of which are incorporated by reference into this application in their entirety, describes systems and method for allowing a user to select a type of tensor and build the selected type of tensor from the data from the DUT. The tensor is then sent to the machine learning network.

In prior systems, no pathway exists to efficiently update the training of the neural network with new data for the device that it could not predict but could still be tuned by the user process. Updating these prior systems requires time consuming and cumbersome retraining of the neural network. Also, prior systems have the disadvantage that they are only trained for one model or type of DUT with a given number of tuning parameters. If it is desired to use a different model of DUT with a different number of tuning parameters, then the system must be retrained.

A need exists for systems that can work on all DUTs with any number of tuning parameters. Users should have the ability to update these systems to tune new types of DUTs, and to add new DUT tuning data, without having to train or re-train neural networks.

### BRIEF DESCRIPTION OF THE DRAWINGS

FIG. 1 shows a waveform image tensor.

FIGS. 2A and 2B shows a block diagram of an embodiment of a machine learning system during training and runtime, respectively.

FIG. 3 shows a block diagram of an embodiment of an AI vector embedding system.

FIGS. 4A and 4B show an embodiment of an AI vector embedding system showing vector database interactions and system behavior.

### DETAILED DESCRIPTION

The embodiments herein involve Artificial Intelligence (AI) to embed waveform image tensors as vectors in a vector database system. This eliminates the need for training of neural networks. The embodiments involve a combination of pretrained neural networks, and a vision transformer and a text transformer within the vector database. The embodiments rely upon tensor building and feature extraction to support specific models of a device under test (DUT). These capabilities exist within Tektronix's OptaML™ system, so users of that system have the possibility of integrating the embodiments into those systems. Further, the embodiments include a new regression classifier that can also integrate into existing systems. The functionalities would be available to new users with the embodiments disclosed here.

The embodiments employ a vector database system that allows users to store and search vectors of complex information. One should note that this particular implementation is not limited to using any specific vector database system, nor limited to any particular module used to associate images with their textual description, typically external to a vector database system with the information being passed between the module and the database.

However, for case of understanding the embodiments here employ a subscription-based vector database called Pinecone. In addition, the embodiments employ CLIP. While Pinecone provides application programming interfaces (APIs) to several image-text pairing embedding models, including CLIP from OpenAI. CLIP, Contrastive Language Image Pretraining, can associate images with their textual descriptors using a combination of image recognition and natural language processing. Other terms in this discussion have particular meanings. “LLM” as used here refers to Large Language Model. “ML” refers to machine learning. “MFG” refers to manufacturing. “RAG” refers to regenerative augmented generation, a means to provide additional information to LLMs. The term “tensor” refers to an image containing extracted waveform features and metadata. It represents the characteristics of a DUT and how its tuning parameters and metadata affect the waveforms.

The main objective of the systems described in the '895 and '896 patents involve tuning DUT parameters on a manufacturing line. In a one-shot tuning prediction, the process feeds a tensor image from the current DUT into a neural network and obtains a set of tuning parameter numbers to store directly into the registers of the DUT. The user no longer needs a tuning procedure that sweeps all the tuning parameters until the tuning process finds the optimal settings. This result greatly speeds up the tuning time on the manufacturing line.

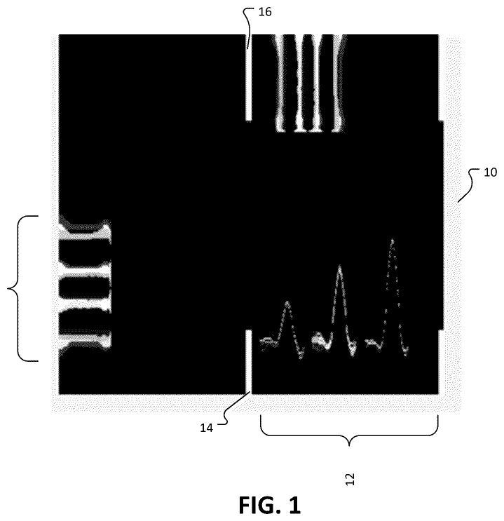

FIG. 1 shows an embodiment of a waveform tensor image 10. The image contains segments of three waveforms 12, each representing a different one of three sets of tuning parameters. The image may also include bar graphs such as 14 and 16 that represent additional information such as temperature and noise, and short pattern segments from the waveforms with multiple instances overlaid such as 18.

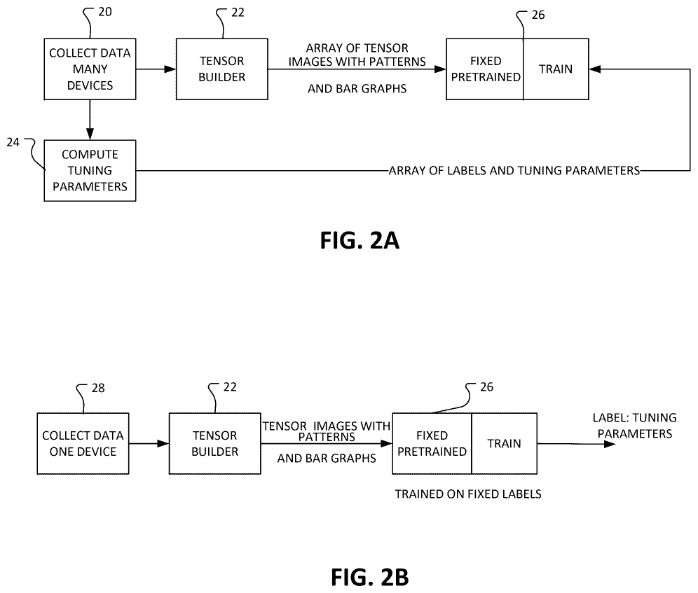

FIGS. 2A and 2B are block diagrams illustrating the training and runtime operation of an example of prior machine learning systems. In FIG. 2A, the neural network 26, in one embodiment the Resnet 18 neural network, undergoes training to receive an image tensor containing waveform segments and other metadata such as temperature and noise. In an example, the user collects waveforms and data from some number of devices under test (DUTs) at 20. For example, the user may collect waveforms and data for 200 DUTs, making an array of 200 image tensors at 22. The user also tunes each DUT and makes an array of 200 optimal tunings to go with the image tensor for each DUT at 24. These two arrays are presented to the neural network 26 and a training operation adapts neural network, training the neural network to associate the image tensor with the optimal tuning set. In one embodiment, the outer three layers of the Resnet 18 trains to associate an image tensor with an optimal tuning set. The remaining layers in the pretrained Resnet 18 network remain unchanged in a transfer learning process.

FIG. 2B shows operation of a trained system during runtime, where the neural network has been trained on a specific model of a DUT with a specific number of tuning parameters. During runtime of these prior systems, the neural network 26, it may be used to make tuning predictions for each DUT during a manufacturing process. The user loads the DUT to be tuned with the same three sets of reference parameters that were used during training and collects data on that DUT at 28. The tensor builder 22 then builds a tensor image using the three waveforms acquired from the DUT, and possibly any other information to be included in bar graphs, etc. Neural network 26 receives the resulting tensor. The neural network outputs the optimal set of tuning parameters that are register values to be stored in the registers of the DUT. The user can then validate the tuning. If the DUT passes, the user moves on to the next DUT. If it fails, the user will try tuning with their original, slower algorithm to make the final call as to pass or fail.

The embodiments herein generally use AI embedding into a vector database to gain the advantage of not having to train neural networks to add new DUT models, or new data for existing models. The AI embedding model may need pretraining, but if so, it can be done. If the embedded vectors of text plus images differ enough, and are unique for all examples, then pretraining is not needed. The need for pretraining depends on the ability of the embedding model to adequately represent the difference in the tensors that are important for associating with tuning parameters.

Embodiments herein generally use a similar technique of DUT characterization using three or more reference sets of parameters, as described in the '895 patent or the '846 application, for example. Like the '895 patent, embodiments of the disclosure also use a similar tensor builder to place the three or more acquired waveforms into an image tensor. However, some embodiments of the disclosure may also use text language embedding associated with the DUT for enhanced ability.

Embodiments herein differ from prior systems by using an AI embedding model and a vector database. They still generally use a pre-trained neural network, such as Resnet 18, for example. However, the neural network does not undergo training on directly output tuning parameters, as was done in prior systems such as that shown in FIGS. 2A and 2B. Instead, the neural network undergoes training to output a vector in a multi-dimensional space. The image tensor is transformed into a vector embedding stored and indexed into a vector database. This mechanism turns the deep learning network into a component usable for all new DUT training data, or for a new DUT model type.

As mentioned above, the embodiments herein employ the CLIP embedding model. Other types of embedding models perform similar functions such as BLIP/2, FLIP, SigLIP, etc., perform similar types of image-text pairs. These models take an image and a text language string as inputs and convert them into vectors to be stored in a vector database. There are various types of AI embedding models available, each specializing in different data types such as language, audio, images, and video. Some embodiments of the disclosure use the CLIP model, which incorporates Resnet 18, a pre-trained deep learning network that performs well in lower-level feature extraction for waveform tensors. However, embodiments are not limited to use of the CLIP model. Networks like the CLIP model can extract key waveform features that are best associated with tuning parameters. The CLIP model also contains a ViT (vision transformer), which may offer additional advantages. Additionally, the model includes a language transformer that can embed language associated with the image.

The additional text may be used to aid in vector matching by including metadata such as the temperature of the DUT, measured noise on the waveforms that were filtered out for feature extraction, the DUT model number, and any other relevant information. This allows the system to isolate vector database match searches to smaller sets of vectors, speeding up the search process and reducing costs for the subscription service or other vector database applications that may be used for embodiments of this disclosure.

The AI embedding model may require pretraining to better address the kind of input tensor images and text that are expected. This pretraining furthers the objective that this AI embedding model once deployed will work with a wide range of DUTs that all generate similar kinds of tensor images. The metadata text with measurements and model number and other metadata makes this feasible as those are important parts of reducing the set of vectors to search to make a tuning match. This mechanism takes some of the image resolution distinction load from the tensor image and the Resnet 18 neural network. This enables the neural network to work for a wider range of DUT types and conditions, making the system more generalized and able to handle a wider range of use cases without re-training.

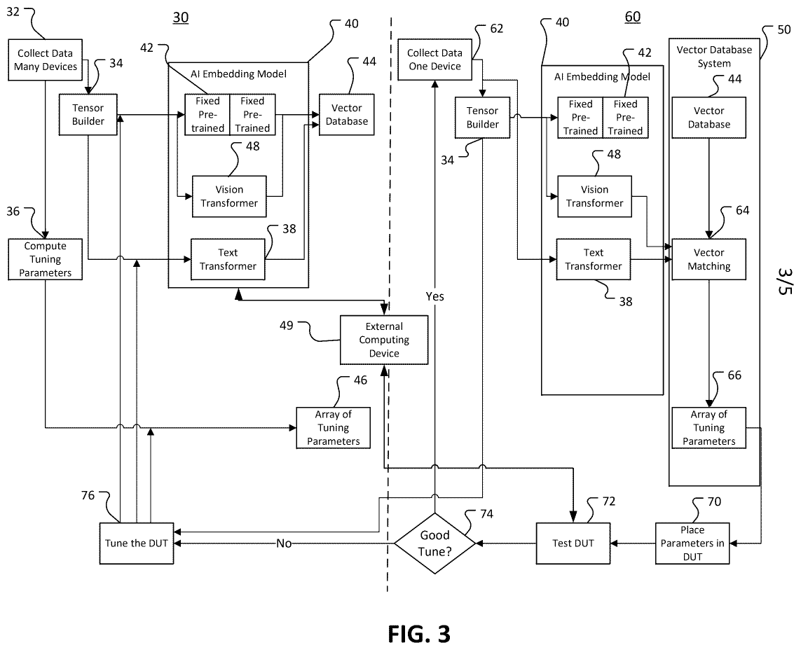

FIG. 3 shows a block diagram of a test and measurement system for both training and runtime. The left side of the figure shows the system in pretraining 30. The right side shows the system in runtime 30. While the system components are the same and shown twice for case of understanding, the two processes of pretraining and runtime connect when the runtime system does not provide the DUT the needed parameters to pass testing. Those system components may have different reference numbers between the two processes if they result in or from a different process.

External computing device 49 is shown as bridging between the two. The computing device may comprise a manufacturing computer that operates the user testing process and interacts with the test and measurement instrument 72 that tests the DUT from FIG. 2B, the vector database 44, and the AI embedding model 40. The AI embedding model may comprise code being executed by one or more processors on the external computing device or may comprise code operated on a remote server. The vector database may also operate as a local database on the computing device or maybe also run on a separate server. The test and measurement system has one or more processors located wherever in the system that execute the code to perform various operations and tasks.

Pretraining the system involves collecting data from many DUTs as the main starting point. In some embodiments, data is collected from around 200 nominal DUTs at 32. This process has many similarities to the prior art OptaML system. The system of FIG. 3 also determines some number of reference parameter sets to load into all DUTs, collecting the number of waveforms from each set for each DUT, extracting features from the waveforms and putting them into tensor images 34 and the language text 38. This process produces an array of tensor images plus text that represent the variations of a group of DUTs. The process also includes optimally tuning these sample DUTs at 36 and saving the optimal tuning sets into an array of optimal tuning sets 46.

Unlike the previous system, the system of the embodiments does not use the array of optimal tuning parameters and the tensor image array to train a neural network. Instead, the tuning array is saved for reference at a later time to retrieve an optimal tuning set. The array of tensor images is input into the CLIP AI embedding model to convert it into an indexed array of vectors. These vectors are stored in the vector database, and the index associated with these vectors is the same index into the associated array of tuning parameters 46. Once the vector database contains a set of vectors representing many different DUTs, and the associated array of optimal tuning parameters is created, the system is ready to use in the runtime state on the MFG line to tune new DUTs.

One the system has been trained, meaning that the vector database has been populated with a set of embedded vectors from the AI embedding model, the user can begin using the system during runtime 60. The user then takes a single device, with the understanding that some manufacturing lines may operate on multiple DUTs in parallel and gathers the resulting waveforms from the DUT at 62. The tensor builder 34 builds a tensor, and the embedding model 40 and the neural network 42 operate as before to provide text from the text transformer 38 and the vision transformer 48, if used, to generate an embedded AI vector. The vector database 44 then performs a vector matching process 64 to produce a set of vectors that contain the optimal tuning parameters for the DUT at 66. The tuning parameters are extracted from the vector and placed in the DUT 70. The process then tests the DUT at 72. If the DUT passes at 74, the system returns to the runtime side and moves on to test the next DUT(s).

If the DUT fails with one of the sets of tuning parameters, the process may iterate. Unlike the previous system, the vector matching process produces some number of vectors, and therefore some number of sets of tuning parameters from the array of optimal tuning parameters 66 on the runtime side, that closely match the optimal tuning parameters. The iterations involve the others of the number of tuning parameters being placed on the DUT and then tested. If, at 74, all the sets of tuning parameters have failed, the process moves on to tune the DUT at 76. The DUT is tuned by the user's previous process at 76. If the DUT still fails at this point, it is either discarded or sent for repair. If the DUT is tuned, the image tensor built for this DUT is retrieved from the tensor builder at runtime and the information is then used to generate a new embedded vector with the image tensor from the runtime side, updated with the turning parameters that succeeded and related text. This is then used to update the vector database. This ensures that the database continues to grow and improve over time, as new DUT models are added and optimized for performance. The iterative process of tuning and adding new models to the database helps to enhance the system's accuracy and efficiency, ultimately leading to better results and higher productivity.

However, if the DUT tunes successfully, a new tensor image and optimal set of tuning parameters are added to the vector database and the optimal tuning array, respectively. This ensures that the database continues to grow and improve over time, as new DUT models are added and optimized for performance. The iterative process of tuning and adding new models to the database helps to enhance the system's accuracy and efficiency, ultimately leading to better results and higher productivity.

The vector database 50 may comprise a Pinecone database, a subscription service for vector databases. This particular vector database offers a wide range of functionalities to manage and grow the database while in use. Currently, it makes a good choice for implementing code with minimal effort, as it provides high-level commands that make it very easy to use. Pinecone also supports many different types of AI embedding models that can be specified for creating vector embeddings, such as CLIP. However, embodiments of the disclosure are not limited to using Pinecone.

In addition to its support for various AI embedding models, Pinecone also offers multiple types of queries and data retrieval from the vector database. The embodiments herein generally use image-to-image queries using the CLIP AI embedding model to convert images into vectors. These are the vectors used to access the optimal tuning parameter array and read out the optimal tuning parameters. This process ensures that the new DUT is tuned optimally, as the system identifies the best tuning parameters by comparing the vectorized image of the new DUT with those of the DUT models stored in the database.

Even if the closest match tuning is not optimal, it should be very close to the optimal tuning, which means that the user algorithm for sweep tuning can begin from a close starting point. As a result, the sweep tuning process should take less time than starting from normal default states to sweep. This is because the closest match tuning provides a good starting point for the user algorithm, reducing the amount of time and effort required to sweep tune the DUT. By using the vector database and the closest match tuning as a starting point, the system can significantly improve the efficiency and accuracy of the tuning process, ultimately leading to better results and higher productivity.

As the vector database grows and more DUT models are added and tuned, it becomes increasingly likely that one-shot tuning is sufficient for each new DUT. This means that the number of times the user tuning algorithm is required will decrease over time as the database becomes more comprehensive and accurate.

If the AI embedding model does not produce the required resolution for image match differences, it can be re-trained once to better fit more variations of input. However, it is expected that only one-time training is necessary, and during runtime, no additional training is required as new data is added to the vector database. By re-training the AI embedding model, the system can improve its accuracy and efficiency in identifying the optimal tuning parameters for new DUTs. However, it is expected that this re-training will only be necessary in rare cases, and that the system will continue to work reliably and accurately with the existing vector database and AI embedding model. Ultimately, the goal is to create a system that is self-sufficient and requires minimal maintenance or adjustments, allowing engineers to focus on other aspects of their work without worrying about the tuning process.

By comparing FIGS. 2A and 2B to FIG. 3, one can see the differences between the prior art tuning system and the new tuning system. A main difference between the two is that in the prior art system, the neural network underwent training on a fixed set of labels and cannot add new labels without retraining. In contrast, the new system uses a neural network that outputs generic image embedded vectors, which are stored in a vector database. This makes it possible to add new labels and DUT models without the need to retrain the neural network. The optimal tuning set results from matching the input image to an existing one in the vector database. This approach allows the system to quickly and accurately identify the optimal tuning parameters for each new DUT model type added to the system, without requiring extensive training or retraining of the neural network. Overall, the new tuning system is more flexible, efficient, and scalable than the prior art system, making it easier for engineers to optimize the performance of new DUT models and improve overall productivity.

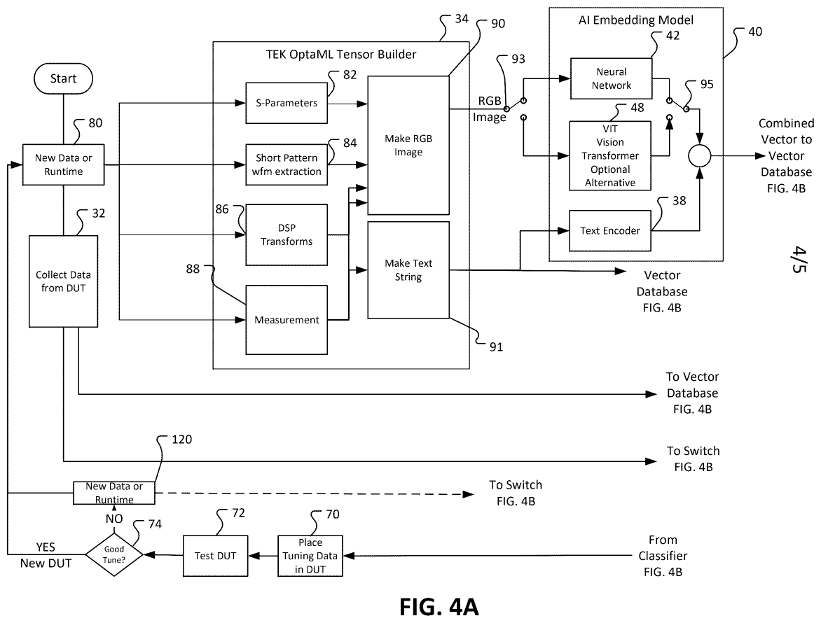

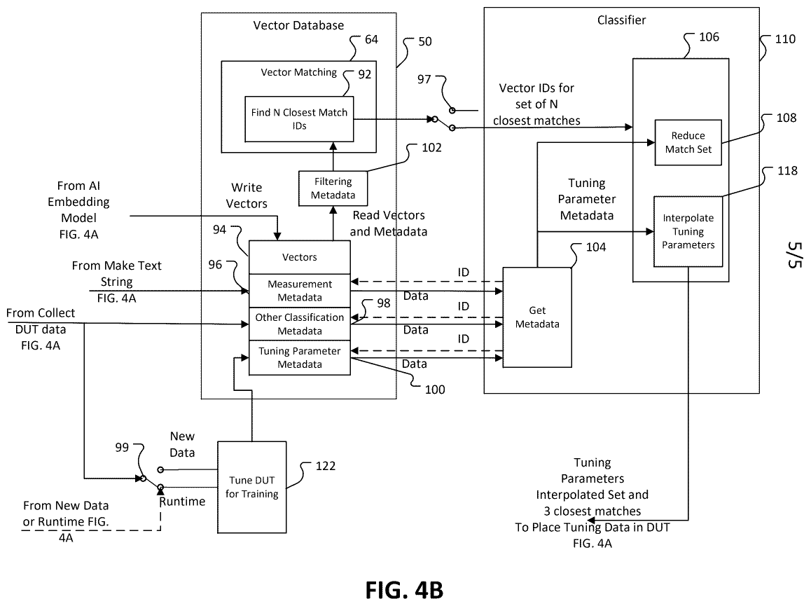

FIGS. 4A and 4B show an embodiment of an overall system with more detail regarding the interactions between the various parts. The two figures are designed to be placed side by side to show the connections between all the components of the system. The overall system includes the tensor builder 34, the AI embedding model 40, the vector database 50, and a post-processing classifier module 110. The system operates in either adding new data mode, or runtime mode, as shown at 80. The data therefore comprises either data for a new DUT that did not previously exist in the vector database, or the current DUT being tested. The tensor builder 34 places the three or more acquired waveforms into an image tensor. The tensor builder may extract S-parameters 82, short pattern waveforms 84, DSP transforms 86 such as Fast Fourier Transforms, bispectrum transforms, filtering, correlation, or others, and measurements 88. The measurements may include frequency, amplitude, pulse width, TDECQ (transmitter and Dispersion Eye Closure Quaternary), noise, temperature, etc., all as were previously included in the image tensor. In addition, the metadata for the DUT may be gathered, including the model, vendor, type, etc. The tensor builder creates an RGB image tensor at 90, where different information may be placed in the different color channels of the image. In addition, the tensor builder also makes a text string of the different information at 91. These pass to the AI embedding model, such a CLIP, mentioned previously. The text string also goes to the vector database, which is shown in FIG. 4B.

The AI embedding model 40 takes the RGB image and uses neural network 42, possibly in conjunction with the vision transformer 48 to develop part of the combined vector. The text transformer/encoder 38 creates the other part, resulting in the embedded combined vector in multidimensional space that is passed to the vector database 50 in FIG. 4B.

In FIG. 4A, the switches 93 and 95 lie in the “neural network” position, selecting between the neural network and the vision transformer.

In FIG. 4B the vector database receives the combined vector from database 50, the text string from the make text string block 91, and the data collected from DUT 32, from FIG. 4A. The combined vector is written into the database at 94, with the measurement metadata 96, any other classification metadata 98 and the tuning parameter metadata 100. This data also passes to the Get Metadata block at 104. Vector Database 50 performs vector matching at 64, with the goal of finding some set N of closest matches at 92. The set of closest matches 92 then pass to the classifier 110. In addition, the vector database then filters the metadata at 102 to allow the vector matching to have closer results to speed up the matches and reduce the amount of time needed to search the vectors.

The classifier 110 then takes the vector IDs for the set of the N closest matches. The processing algorithms 106 operate to reduce the match set at 108. This block receives the N closest match DUT embedding IDs from the vector database. The closest match is with respect to a new DUT that is to be tuned on the MFG line. Some waveform or other types of characterization data are acquired from the DUT using reference parameters in stored in the DUT. Then features and measurements are extracted from the waveforms and incorporated into an image tensor and text tensor and metadata to obtain the embedding object set that will be compared to embeddings in the database. This is done by metadata in the embedding vector ID structure to further divide vectors into classification groups. The interpolation block 118 reads the tuning parameters stored in the metadata set for the embedding ID and performs a regression analysis on each tuning parameter and computes the most likely value of the tuning parameter. This is one of the tuning parameter sets that will be returned to the user to try in their Dut. Other tuning parameters sets will also be returned to the user to try in their DUT. The user may try these different sets in their DUT in order to increase the chances they find a tuning parameter set that passes their requirements for tuning the DUT.

As discussed above, if the closest match is not satisfactory, the system can try the next few closest matches to obtain better results. In addition, the user can also try the regression pseudo interpolated tuning parameter set that was returned. In case one of the matches is deemed optimal, the system moves on to the next DUT to tune. This iterative process ensures that the tuning parameters selected for each DUT are validated and optimized for the best possible performance.

The switches in both FIGS. 4A and 4B show the two states of operation. The first state New Data and the second state is Runtime. The Runtime state is for when a new DUT is to be tuned. Its AI embedding is compared against the embedding in the database, and the N IDs for the closest matches of the vector are returned. These IDs are then processed by the regression classier block to reduce the set and further classify for better accuracy. The closest match is used to retrieve the optimal tuning parameters out of the metadata for the ID to obtain the optical tuning parameters.

When New Data is selected at block 120, the switches change to the New Data setting at each switch. At block 122, the signal is sent to switch 99 in FIG. 4B, as is the new data collection from the DUT from block 32 in FIG. 4A. In addition, switch 97 goes to NC, which disconnects the classifier from the vector database. One can add more data to the vector database without retraining the neural network.

The resulting system has more accuracy when predicting on data it has never seen before. This architecture also includes text in addition to the image, as a part of the vector. This takes a lot of the burden from image interpretation through the neural network. The text metadata is also used to select which folders the vectors go to in the database. This also results in faster vector match operations, because the search is done on a much smaller set of vectors.

Once the system “sees” waveform tensors better, the objective is that training, if needed, would only be done once and work for all future calibration setups using tensor builder images. This would be valid if the embedding of each different tensor image/text is unique and different enough to detect in the cosine matching algorithm. All output predictions are valid optimal tuning sets because they came from an array of optimal tunings, not from potential invalid outputs of the neural network.

The use cases and applications for embodiments herein include one or more of the following, just as examples. One use case comprises tuning optical transmitters on the manufacturing line saving large amounts of MFG time. Another comprises tuning oscilloscope non-linear correction and/or frequency response calibration parameters on the MFG saving time. The embodiments reducing data set sweeps for testing die prior to installing them in a package to save MFG time. Another comprises diplexer and duplexer tuning for wireless communications antennas. This case uses S-parameters as tensor image inputs.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried out by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 1 is a test and measurement system, comprising: a test and measurement instrument, comprising: a connection to allow the test and measurement instrument to connect to a device under test (DUT); one or more analog-to-digital converters (ADCs) to receive a signal from the DUT and convert it to one or more digital waveforms; and one or more processors, configured to execute code that causes the one or more processors to: receive the one or more digital waveforms from the one or more ADCs, each of the one or more digital waveforms corresponding to one set of tuning parameters applied to the DUT; build one or more image tensors of the one or more digital waveforms; use an artificial intelligence embedding model that generates one or more text strings from metadata associated with the waveforms and embeds the metadata and the one or more image tensors into a vector; access a vector database; receive, from the vector database, a set of indexes, the set of indexes having a number of indexes corresponding to a number of matches; use the set of indexes to access an array of optimal tuning parameters to find one or more sets of optimal tuning parameters for the DUT; and validate operation of the DUT with the one or more sets of optimal tuning parameters from the array of optimal tuning parameters.

Example 2 is the test and measurement system of Example 1, wherein the code that causes the one or more processors to validate operation of the DUT comprises code that causes the one or more processors to: tune the DUT with one of the one or more sets of optimal tuning parameters; test the DUT with the one of the one or more sets of optimal tuning parameters; determine if the DUT passes the test; use another one of the one or more sets of optimal tuning parameters when the DUT fails the test; and repeat until one of either the DUT has passed the test, or all sets of the one or more sets of optimal tuning parameters have been tested.

Example 3 is the test and measurement system of Example 2, wherein the one or more processors are further configured to execute code that causes the one or more processors to employ a user testing process.

Example 4 is the test and measurement system of Example 3, wherein the code that causes the one or more processors to employ a user testing process comprises code that causes the one or more processors to start the user testing process using a closest set of the one or more sets of optimal tuning parameters.

Example 5 is the test and measurement system of Example 3, wherein the code that causes the one or more processors to employ a user testing process comprises code that causes the one or more processors to update the artificial intelligence embedding model with a text string from metadata associated with the waveforms and the one or more image tensors.

Example 6 is the test and measurement system of Example 3, wherein the code that causes the one or more processors to employ a user testing process comprises code that causes the one or more processors to discard or repair the DUT when the DUT cannot be tuned.

Example 7 is the test and measurement system of any of Examples 1 through 6, wherein the one or more processors are further configured to execute code that causes the one or more processors to use the metadata to reduce the number of indexes before the one or more processors use the indexes.

Example 8 is the test and measurement system of any of Examples 1 through 7, wherein the one or more processors are further configured to execute code that causes the one or more processors to read the tuning parameters from the metadata and perform a regression analysis to determine a most likely value of the tuning parameter and return a regression tuning parameter set.

Example 9 is the test and measurement system of Example 8, wherein the one or more processors are further configured to use the regression tuning parameter set when the DUT cannot be tuned by either the indexes returned from the artificial intelligence vector system or a user testing process.

Example 10 is the test and measurement system of any of Examples 1 through 9, wherein the one or more processors are further configured to execute code to cause the one or more processors to train the artificial intelligence embedding model.

Example 11 is the test and measurement system of any of Examples 1 through 10, wherein the code that causes the one or more processors to train the artificial intelligence embedding model comprises code that causes the one or more processors to: collect tuning data on a predetermined number of DUTs, the tuning data comprising an array of optimal tuning parameters, tensor images, and text; and input the tuning data to the artificial intelligence embedding model to allow the artificial intelligence embedding model to convert the tuning data and to update the vector database.

Example 12 is a method of testing a device under test (DUT), comprising: receiving or more digital waveforms from one or more analog-to-digital converters (ADCs), each digital waveform corresponding to one set of tuning parameters applied to the DUT; building one or more image tensors of the one or more digital waveforms; using an artificial intelligence embedding model that generates one or more text strings from metadata associated with the waveforms and embeds the metadata and the one or more image tensors; accessing a vector database to compare the vector to vectors in the database; receiving, from the vector database, a set of indexes, the set of indexes having a number of indexes corresponding to a number of matchers; using the set of indexes to access an array of optimal tuning parameters to find one or more sets of optimal tuning parameters for the DUT; and validating operation of the DUT with one of the one or more sets of optimal tuning parameters from the array of optimal tuning parameters.

Example 13 is the method claimed in claim 12, wherein validating operation of the DUT comprises: tuning the DUT with one set of the one or more sets of optimal tuning parameters; testing the DUT with the one of the one or more sets of optimal tuning parameters with the test and measurement instrument; determining if the DUT passes the test; using another one of the one or more sets of optimal tuning parameters when the DUT fails the test; and repeating until one of either of the DUT has passed the test or all sets of the one or more sets or optimal tuning parameters have been tested.

Example 14 is the method of Example 13, further comprising employing a user testing process.

Example 15 is the method of Example 14, wherein employing a user testing process comprises starting the user testing process using a closest of the sets of one or more optimal tuning parameters.

Example 16 is the method of Example 14, wherein employing a user testing process comprises updating the vector database with a new vector by using the artificial intelligence embedding model to generate the new vector from one or more text strings from metadata associated with the waveforms, the one or more image tensors, and the metadata.

Example 17 is the method of Example 14, wherein employing a user testing process comprises discarding or repairing the DUT when the DUT cannot be tuned.

Example 18 is the method of any of Examples 12 through 17, further comprising using the metadata to reduce the number of indexes before the one or more processors use the indexes.

Example 19 is the method of any of Examples 12 through 18, further comprising reading the tuning parameters from the metadata and performing a regression analysis to determine a most likely value of the tuning parameter and return a regression tuning parameter set.

Example 20 is the method of any of Examples 12 through 19, further comprising using the regression tuning parameter set when the DUT cannot be tuned by either the indexes returned from the vector database or a user testing process.

Example 21 is the method of any of Examples 12 through 20, further comprising training the artificial intelligence embedding model.

Example 22 is the test and measurement instrument of Example 21, wherein training the artificial intelligence embedding model comprises: collecting tuning data on a predetermined number of DUTs, the tuning data comprising an array of optimal turning parameters, tensor images, and text formed into vectors; and inputting the vectors into the vector database to populate the vector database.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific aspects of this disclosure have been illustrated and described for purposes of illustration, it will be understood that various modifications may be made without departing from the spirit and scope of the invention. Accordingly, the invention should not be limited except as by the appended claims.

1. A test and measurement system, comprising:
a test and measurement instrument, comprising:
a connection to allow the test and measurement instrument to connect to a device under test (DUT);
one or more analog-to-digital converters (ADCs) to receive a signal from the DUT and convert the signal to one or more digital waveforms; and
one or more processors, configured to execute code that causes the one or more processors to:
receive the one or more digital waveforms from the one or more ADCs, each of the one or more digital waveforms corresponding to one set of tuning parameters applied to the DUT;
build one or more image tensors of the one or more digital waveforms;
use an artificial intelligence embedding model that generates one or more text strings from metadata associated with the waveforms and embeds the metadata and the one or more image tensors into a vector;
access a vector database;
receive, from the vector database, a set of indexes, the set of indexes having a number of indexes corresponding to a number of matches;
use the set of indexes to access an array of optimal tuning parameters to find one or more sets of optimal tuning parameters for the DUT; and
validate operation of the DUT with the one or more sets of optimal tuning parameters from the array of optimal tuning parameters.

2. The test and measurement system as claimed in claim 1, wherein the code that causes the one or more processors to validate operation of the DUT comprises code that causes the one or more processors to:
tune the DUT with one of the one or more sets of optimal tuning parameters;
test the DUT with the one of the one or more sets of optimal tuning parameters;
determine if the DUT passes the test;
use another one of the one or more sets of optimal tuning parameters when the DUT fails the test; and
repeat until one of either the DUT has passed the test, or all sets of the one or more sets of optimal tuning parameters have been tested.

3. The test and measurement system as claimed in claim 2, wherein the one or more processors are further configured to execute code that causes the one or more processors to employ a user testing process.

4. The test and measurement system as claimed in claim 3, wherein the code that causes the one or more processors to employ a user testing process comprises code that causes the one or more processors to start the user testing process using a closest set of the one or more sets of optimal tuning parameters.

5. The test and measurement system as claimed in claim 3, wherein the code that causes the one or more processors to employ a user testing process comprises code that causes the one or more processors to update the artificial intelligence embedding model with a text string from metadata associated with the waveforms and the one or more image tensors.

6. The test and measurement system as claimed in claim 3, wherein the code that causes the one or more processors to employ a user testing process comprises code that causes the one or more processors to discard or repair the DUT when the DUT cannot be tuned.

7. The test and measurement system as claimed in claim 1, wherein the one or more processors are further configured to execute code that causes the one or more processors to use the metadata to reduce the number of indexes before the one or more processors use the indexes.

8. The test and measurement system as claimed in claim 1, wherein the one or more processors are further configured to execute code that causes the one or more processors to read the tuning parameters from the metadata and perform a regression analysis to determine a most likely value of the tuning parameter and return a regression tuning parameter set.

9. The test and measurement system as claimed in claim 8, wherein the one or more processors are further configured to use the regression tuning parameter set when the DUT cannot be tuned by either the indexes returned from the artificial intelligence vector system or a user testing process.

10. The test and measurement system as claimed in claim 1, wherein the one or more processors are further configured to execute code to cause the one or more processors to train the artificial intelligence embedding model.

11. The test and measurement system as claimed in claim 1, wherein the code that causes the one or more processors to train the artificial intelligence embedding model comprises code that causes the one or more processors to:
collect tuning data on a predetermined number of DUTs, the tuning data comprising an array of optimal tuning parameters, tensor images, and text; and
input the tuning data to the artificial intelligence embedding model to allow the artificial intelligence embedding model to convert the tuning data and to update the vector database.

12. A method of testing a device under test (DUT), comprising:
receiving or more digital waveforms from one or more analog-to-digital converters (ADCs), each digital waveform corresponding to one set of tuning parameters applied to the DUT;
building one or more image tensors of the one or more digital waveforms;
using an artificial intelligence embedding model that generates one or more text strings from metadata associated with the waveforms and embeds the metadata and the one or more image tensors;
accessing a vector database to compare the vector to vectors in the database;
receiving, from the vector database, a set of indexes, the set of indexes having a number of indexes corresponding to a number of matchers;
using the set of indexes to access an array of optimal tuning parameters to find one or more sets of optimal tuning parameters for the DUT; and
validating operation of the DUT with one of the one or more sets of optimal tuning parameters from the array of optimal tuning parameters.

13. The method claimed in claim 12, wherein validating operation of the DUT comprises:
tuning the DUT with one set of the one or more sets of optimal tuning parameters;
testing the DUT with the one of the one or more sets of optimal tuning parameters with the test and measurement instrument;
determining if the DUT passes the test;
using another one of the one or more sets of optimal tuning parameters when the DUT fails the test; and
repeating until one of either of the DUT has passed the test or all sets of the one or more sets or optimal tuning parameters have been tested.

14. The method as claimed in claim 13, further comprising employing a user testing process.

15. The method as claimed in claim 14, wherein employing a user testing process comprises starting the user testing process using a closest of the sets of one or more optimal tuning parameters.

16. The method as claimed in claim 14, wherein employing a user testing process comprises updating the vector database with a new vector by using the artificial intelligence embedding model to generate the new vector from one or more text strings from metadata associated with the waveforms, the one or more image tensors, and the metadata.

17. The method as claimed in claim 14, wherein employing a user testing process comprises discarding or repairing the DUT when the DUT cannot be tuned.

18. The method as claimed in claim 12, further comprising using the metadata to reduce the number of indexes before the one or more processors use the indexes.

19. The method as claimed in claim 12, further comprising reading the tuning parameters from the metadata and performing a regression analysis to determine a most likely value of the tuning parameter and return a regression tuning parameter set.

20. The method as claimed in claim 12, further comprising using the regression tuning parameter set when the DUT cannot be tuned by either the indexes returned from the vector database or a user testing process.

21. The method as claimed in claim 12, further comprising training the artificial intelligence embedding model.

22. The test and measurement instrument as claimed in claim 21, wherein training the artificial intelligence embedding model comprises:
collecting tuning data on a predetermined number of DUTs, the tuning data comprising an array of optimal turning parameters, tensor images, and text formed into vectors; and
inputting the vectors into the vector database to populate the vector database.
